(19) United States
(12) Patent Application Publication
(10) Pub. No.: US 2019/0296195 A1
(43) Pub. Date: Sep. 26, 2019

(54) SUBSTRATE FOR OPTICAL DEVICE, OPTICAL DEVICE PACKAGE, MANUFACTURING METHOD OF SUBSTRATE FOR OPTICAL DEVICE, AND MANUFACTURING METHOD OF OPTICAL DEVICE PACKAGE

(71) Applicant: POINT ENGINEERING CO., LTD., Asan (KR)

(72) Inventors: Bum Mo AHN, Suwon (KR); Seung Ho PARK, Hwaseong (KR); Tae Hwan SONG, Cheonan (KR)

(21) Appl. No.: 16/357,204

(22) Filed: Mar. 18, 2019

(30) Foreign Application Priority Data
Mar. 20, 2018 (KR) 10-2018-0031821

(51) Int. Cl. H01L 33/48; H01L 33/62; H01L 33/60

(52) U.S. Cl. CPC H01L 33/486; H01L 33/60; H01L 33/62

(57) ABSTRACT

The present invention relates generally to a substrate for an optical device, an optical device package, a manufacturing method of the substrate for the optical device, and a manufacturing method of the optical device package. More particularly, the present invention relates to a substrate for an optical device, an optical device package, a manufacturing method of the substrate for the optical device, and a manufacturing method of the optical device package, in which the optical device to be mounted self-aligns, thus improving mounting precision of the optical device, and also reflection efficiency is prevented from being reduced.

### CROSS REFERENCE TO RELATED APPLICATION

The present application claims priority to Korean Patent Application No. 10-2018-0031821, filed Mar. 20, 2018, the entire contents of which is incorporated herein for all purposes by this reference.

### BACKGROUND OF THE INVENTION

### Field of the Invention

The present invention relates generally to a substrate for an optical device, an optical device package, a manufacturing method of the substrate for the optical device, and a manufacturing method of the optical device package. More particularly, the present invention relates to a substrate for an optical device, an optical device package, a manufacturing method of the substrate for the optical device, and a manufacturing method of the optical device package, in which the optical device is prevented from being tilted when mounted.

### Description of the Related Art

In general, an optical device package refers to a device in which optical devices are mounted to generate light. In this case, the optical devices mean devices that generate light in response to an electrical signal. Of these optical devices, light emitting diodes (LEDs), which generate light of high luminance as well as being more efficient than conventional optical devices, have been widely used in display fields. The optical device package is manufactured by mounting optical devices and the like on a substrate for an optical device. The optical devices described in this specification include infrared LEDs, visible-light LEDs, and ultraviolet LEDs.

A conventional metal substrate on which a vertical insulating layer is formed is manufactured in such a manner that the metal substrate and the insulating layer are alternately laminated (or formed) and then cut vertically by a predetermined length (width). The materials of the metal substrate on which the vertical insulating layer is formed include aluminum, copper, and an alloy containing at least one of these materials having good thermal conductivity and electrical conductivity. Furthermore, the metal substrate on which the vertical insulating layer is formed has a tapered cavity formed in a top surface thereof by means of mechanical processing or chemical etching. Meanwhile, a metal plating layer, for example, a silver (Ag) plating layer is formed on the peripheral wall of the cavity and the top surface of the metal substrate by means of electrolytic or electroless plating or sputtering in order to improve reflection performance of light generated in an optical device or bonding performance. The optical device is bonded to a part of a top surface of the silver plating layer in the cavity with an Ag epoxy adhesive.

The above-described Ag epoxy, which has good electrical conductivity and bonding properties but has a relatively low thermal conductivity, causes thermal resistance in a package in which a high-power optical device is mounted, thus serving as a factor that degrades heat a dissipation property of the entire package. This results in shortening the life span of the optical device. Furthermore, if the optical device is an ultraviolet LED which generates more heat than a visible-light LED, the above-mentioned problem will become more significant.

In an effort to solve such a problem, the present applicant invented a manufacturing method and structure for bonding an optical device chip by means of Au/Sn soldering as disclosed in Korean Patent No. 10-1373710 (hereinafter, referred to as “related art”). The related art includes: forming at least one cavity having a predetermined depth and recessed in a metal substrate that is electrically divided by at least one vertical insulating layer, and having the at least one vertical insulating layer provided below the bottom thereof; shadow masking the entire surface of the metal substrate except for a part of an top surface thereof in each cavity; removing an oxide film formed on the part of the top surface of the metal substrate in each cavity which is not subjected to masking; depositing an electrode layer on the part of the top surface of the metal substrate in each cavity; wire bonding an electrode of the optical device located on the metal substrate at a first side with respect to each vertical insulating layer to the metal substrate located at a second side with respect to each vertical insulating layer by means of a wire.

However, in the related art, the electrode layer is formed in an island shape by using a shadow mask, and thus in the case of forming a deep cavity, there may be a limit in achieving precision in formation of the island-shaped electrode layer. Additionally, since the electrode layer is partially formed, there may be a limit in improving reflection efficiency.

As described above, there may be a problem in that it is difficult to mount the optical device precisely at a correct position when mounting the optical device in an optical device package in the related art. Additionally, even when mounting precision of the optical device is achieved, reflection efficiency may be reduced. Accordingly, there is a need to precisely mount the optical device at the correct position while preventing a reduction in reflection efficiency.

The foregoing is intended merely to aid in the understanding of the background of the present invention, and is not intended to mean that the present invention falls within the purview of the related art that is already known to those skilled in the art.

### DOCUMENTS OF RELATED ART

(Patent document 1) Korean Patent No. 10-1373710

### SUMMARY OF THE INVENTION

Accordingly, the present invention has been made keeping in mind the above problems occurring in the related art, and an objective of the present invention is to provide a substrate for an optical device, an optical device package, a manufacturing method of the substrate for the optical device, and a manufacturing method of the optical device package, in which the optical device to be mounted self-aligns, thus improving mounting precision of the optical device, and also reflection efficiency is prevented from being reduced.

In order to achieve the above objective, according to one aspect of the present invention, there is provided a substrate for an optical device, the substrate including: first and second metal members bonded together with a vertical insulating part interposed therebetween; a first island plating layer formed on a top surface of the first metal member; a space region formed outside of the first island plating layer to expose the top surface of the first metal member; a first peripheral plating layer formed on the top surface of the first metal member at a position except for the first island plating layer and the space region; and a second plating layer formed on a top surface of the second metal member.

Furthermore, the first island plating layer may have a polygonal shape, and the space region may be formed between the first island plating layer and the first peripheral plating layer such that the first island plating layer and the first peripheral plating layer are isolated from each other.

Furthermore, the first island plating layer, the first peripheral plating layer, and the second plating layer may be made of the same metal.

Furthermore, the first peripheral plating layer, the space region, and the first island plating layer may be located at a first side with respect to the vertical insulating part, the second plating layer may be located at a second side with respect to the vertical insulating part, and the second plating layer, the vertical insulating part, the first peripheral plating layer, the space region, and the first island plating layer may be located sequentially along a line intersecting with the vertical insulating part.

According to another aspect of the present invention, there is provided a substrate for an optical device, the substrate including: first and second metal members bonded together with a vertical insulating part interposed therebetween; a first island plating layer formed on a top surface of the first metal member; a first space region famed outside of the first island plating layer to expose the top surface of the first metal member; a first peripheral plating layer formed on the top surface of the first metal member at a position except for the first island plating layer and the first space region; a second island plating layer formed on a top surface of the second metal member; a second space region formed outside of the second island plating layer to expose the top surface of the second metal member; and a second peripheral plating layer famed on the top surface of the second metal member at a position except for the second island plating layer and the second space region.

Furthermore, the first space region may have a ‘ [symbol] ’-shape, the second space region may have a ‘ [symbol] ’-shape, and the vertical insulating part may be located between the first and second space regions that face each other.

According to still another aspect of the present invention, there is provided an optical device package, including: first and second metal members bonded together with a vertical insulating part interposed therebetween; a first island plating layer formed on a top surface of the first metal member; a space region formed outside of the first island plating layer to expose the top surface of the first metal member; a first peripheral plating layer formed on the top surface of the first metal member at a position except for the first island plating layer and the space region; a second plating layer formed on a top surface of the second metal member; a solder provided on the first island plating layer; an optical device provided on the solder and having a first terminal electrically connected to the first metal member; and a wire electrically connecting a second terminal of the optical device to the second metal member.

Furthermore, the first and second metal members may be metals that have no affinity for the solder.

According to still another aspect of the present invention, there is provided an optical device package, including: first and second metal members bonded together with a vertical insulating part interposed therebetween; a first island plating layer formed on a top surface of the first metal member; a first space region famed outside of the first island plating layer to expose the top surface of the first metal member; a first peripheral plating layer formed on the top surface of the first metal member at a position except for the first island plating layer and the first space region; a second island plating layer formed on a top surface of the second metal member; a second space region formed outside of the second island plating layer to expose the top surface of the second metal member; a second peripheral plating layer formed on the top surface of the second metal member at a position except for the second island plating layer and the second space region; a first solder provided on the first island plating layer; a second solder provided on the second island plating layer; and an optical device having a first terminal provided on the first solder and electrically connected to the first metal member, and a second terminal provided on the second solder and electrically connected to the second metal member.

According to still another aspect of the present invention, there is provided a manufacturing method of a substrate for an optical device, the manufacturing method including: forming first and second metal members that are bonded together with a vertical insulating part interposed therebetween; forming a cavity having a predetermined depth on top surfaces of the first and second metal members in a region including the vertical insulating part; forming a plating layer on a bottom surface of the cavity; and forming a space region to expose the top surface of the first metal member by patterning with a laser the plating layer that is formed on the bottom surface of the cavity, such that the first island plating layer is located inside of the space region and the first peripheral plating layer is located outside of the space region.

According to still another aspect of the present invention, there is provided a manufacturing method of a substrate for an optical device, the manufacturing method including: forming first and second metal members that are bonded together with a vertical insulating part interposed therebetween; forming a cavity having a predetermined depth on top surfaces of the first and second metal members in a region including the vertical insulating part; forming a plating layer on a bottom surface of the cavity; and forming first and second space regions to expose top surfaces of the first and second metal members, respectively by patterning with a laser the plating layer that is famed on the bottom surface of the cavity, such that the first island plating layer is located inside of the first space region and the first peripheral plating layer is located outside of the first space region, while the second island plating layer is located inside of the second space region and the second peripheral plating layer is located outside of the second space region.

According to still another aspect of the present invention, there is provided a manufacturing method of an optical device package, the manufacturing method including: forming first and second metal members that are bonded together with a vertical insulating part interposed therebetween; forming a cavity having a predetermined depth on top surfaces of the first and second metal members in a region including the vertical insulating part; forming a plating layer on a bottom surface of the cavity; forming a space region to expose the top surface of the first metal member by patterning with a laser the plating layer that is formed on the bottom surface of the cavity, such that the first island plating layer is located inside of the space region and the first peripheral plating layer is located outside of the space region; providing a solder on the first island plating layer; bonding an optical device onto the solder; and connecting a terminal provided on a top surface of the optical device to the second metal member by using a wire.

According to still another aspect of the present invention, there is provided a manufacturing method of an optical device package, the manufacturing method including: forming first and second metal members that are bonded together with a vertical insulating part interposed therebetween; forming a cavity having a predetermined depth on top surfaces of the first and second metal members in a region including the vertical insulating part; forming a plating layer on a bottom surface of the cavity; forming first and second space regions to expose top surfaces of the first and second metal members, respectively by patterning with a laser the plating layer that is formed on the bottom surface of the cavity, such that the first island plating layer is located inside of the first space region and the first peripheral plating layer is located outside of the first space region, while the second island plating layer is located inside of the second space region and the second peripheral plating layer is located outside of the second space region; providing a first solder on the first island plating layer and providing a second solder on the second island plating layer; and bonding the optical device such that first and second terminals thereof are located on the first and second solders.

According to the embodiments of the present invention, it is possible to enable the optical device to be mounted to self-align, thus improving mounting precision of the optical device and also to prevent reflection efficiency from being reduced.

### BRIEF DESCRIPTION OF THE DRAWINGS

The above and other objectives, features and other advantages of the present invention will be more clearly understood from the following detailed description when taken in conjunction with the accompanying drawings, in which:

FIGS. 1A to 1C are views showing a substrate for an optical device in which a vertical insulating part and a cavity are formed according to a first embodiment of the present invention;

FIGS. 2A to 2C are views showing a plating layer formed in FIGS. 1A to 1C;

FIGS. 3A to 3C are views showing a space region formed in FIGS. 2A to 2C;

FIGS. 4A to 4C are views showing a solder provided in FIGS. 3A to 3C;

FIGS. 5A to 5C are views showing the optical device bonded in FIGS. 4A to 4C;

FIGS. 6A to 6C are views showing a substrate for an optical device in which a vertical insulating part and a cavity are formed according to a second embodiment of the present invention;

FIGS. 7A to 7C are views showing a plating layer formed in FIGS. 6A to 6C;

FIGS. 8A to 8C are views showing a space region formed in FIGS. 7A to 7C;

FIGS. 9A to 9C are views showing a solder provided in FIGS. 8A to 8C; and

FIGS. 10A to 10C are views showing the optical device bonded in FIGS. 9A to 9C,

wherein each of the drawings with symbol B is a cross-sectional view taken along line A-A′ of an associated drawing with symbol A, and each of the drawings with symbol C is a plan view of an associated drawing with symbol A.

### DETAILED DESCRIPTION OF THE INVENTION

The following contents merely illustrate a principle of the present invention. Accordingly, even though not being clearly described or shown in the specification, the principle of the present invention may be embodied and various apparatuses included in the concept and scope of the present invention may be made by one of ordinary skill in the art. Also, all conditional terms and embodiments enumerated herein are clearly intended only to allow the concept of the present invention to be understood but not limited to the embodiments and states particularly enumerated as follows.

The above and other objectives, features, and advantages of the present invention will be more clearly understood from the following detailed description taken in conjunction with the accompanying drawings. Accordingly, the invention can be easily embodied by one of ordinary skill in the art to which this invention belongs.

Hereinafter, a unit substrate for an optical device according to exemplary embodiments of the present invention will be described in detail with reference to embodiments shown in the accompanying drawings. For the sake of convenience in describing various embodiments, like reference numerals are used to identify like elements throughout the drawings and different embodiments. In addition, the configurations and operations already described in other embodiments will be omitted for the sake of convenience.

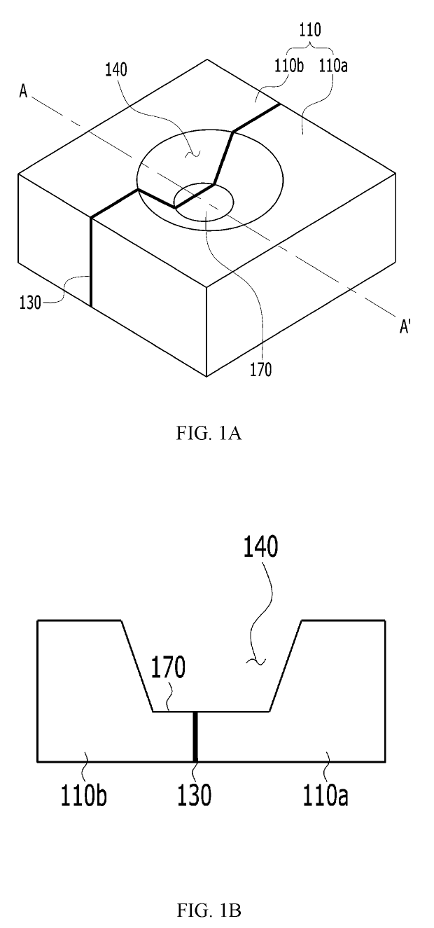

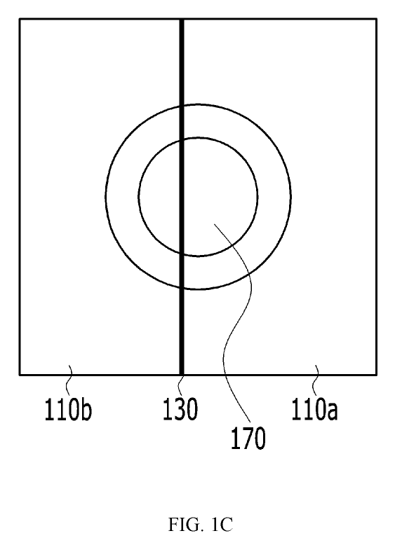

FIGS. 1A to 5C are views showing a substrate for an optical device and a manufacturing method of an optical device package according to a first embodiment of the present invention.

As shown in FIGS. 1A to 1C, first and second metal members 110a and 110b are bonded together with a vertical insulating part 130 interposed therebetween. A cavity 140 having a predetermined depth is provided in top surfaces of the first and second metal members 110a and 110b in a region including the vertical insulating part 130.

The substrate for the optical device shown in FIGS. 1A to 1C is configured such that the first and second metal members 110a and 110b are bonded together to define a metal member 110. In other words, the substrate for the optical device includes the first metal member 110a, the second metal member 110b located on a side surface of the first metal member 110a and bonded to the first metal member 110a, and the vertical insulating part 130 provided at a junction of the first metal member 110a and the second metal member 110b and electrically insulating the first metal member 110a and the second metal member 110b from each other.

It is preferable that the first and second metal members 110a and 110b are made of metal having no affinity for the solder. In the embodiment of the present invention, the first and second metal members 110a and 110b are made of aluminum or an aluminum alloy.

The vertical insulating part 130 is made of a material having an insulating property. The vertical insulating part 130 is provided by using an insulating liquid bonding agent. To improve the bonding strength between the first and second metal members 110a and 110b and the vertical insulating part 130 bonded together by using the liquid bonding agent, a synthetic resin bonding film may be interposed therebetween. Alternatively, at least one surface of each of the first and second metal members 110a and 110b may be subjected to anodizing and the first and second metal members 110a and 110b are bonded together in a state in which the respective anodized surfaces thereof face each other. In other words, when the first and second metal members 110a and 110b are made of aluminum (or aluminum alloy), at least one surface of each of the first and second metal members 110a and 110b is subjected to anodizing before bonding so as to be included in the vertical insulating part 130.

The substrate 100 for the optical device has the cavity 140 recessed in a top surface thereof with a predetermined depth in the region including the vertical insulating part 130. The cavity 140 has a tapered shape in which an upper portion is open and a lower portion is composed of a flat bottom surface 170.

The vertical insulating part 130 is eccentrically located at a predetermined length from a center line of the metal member 110 in a direction of the second metal member 110b. Accordingly, a portion of the bottom surface 170 of the cavity 140 located between the vertical insulating part 130 and the first metal member 110a is larger in area than a remaining portion of the bottom surface 170 of the cavity 140 located between the vertical insulating part 130 and the second metal member 110b.

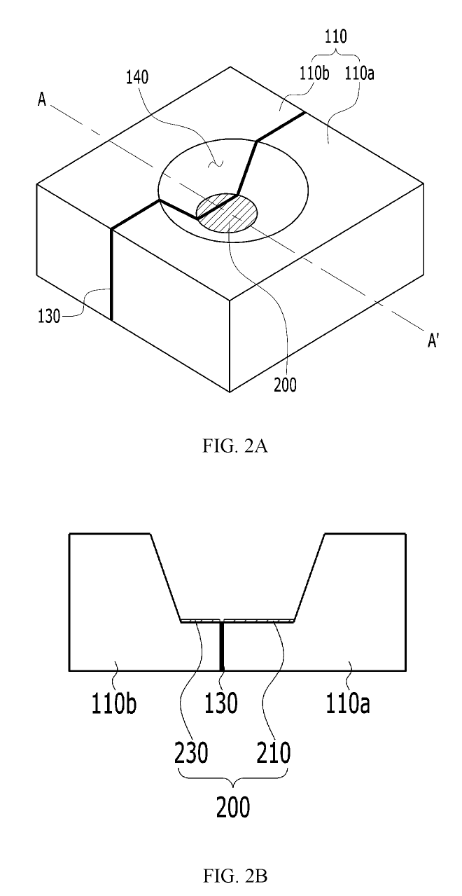

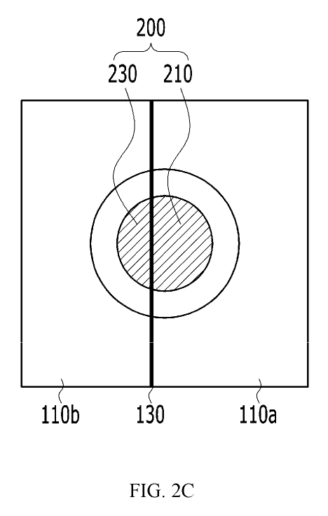

Next, as shown in FIGS. 2A to 2C, a plating layer 200 is formed on the bottom surface 170 of the cavity 140 by using the substrate for the optical device shown in FIGS. 1A to 1C.

The plating layer 200 is not formed on a top surface of the vertical insulating part 130 but includes a first plating layer 210 formed on the top surface of the first metal member 110a and a second plating layer 210 formed on the top surface of the second metal member 110b. The first plating layer 210 is larger in area than the second plating layer 230.

The first and second plating layers 210 and 230 are integrally formed through a single plating process and are made of the same metal. Furthermore, it is preferable that the first and second plating layers are made of metal having a higher reflectivity than the first and second metal members 110a and 110b. It is more preferable that the first and second plating layers are formed by plating with gold or silver.

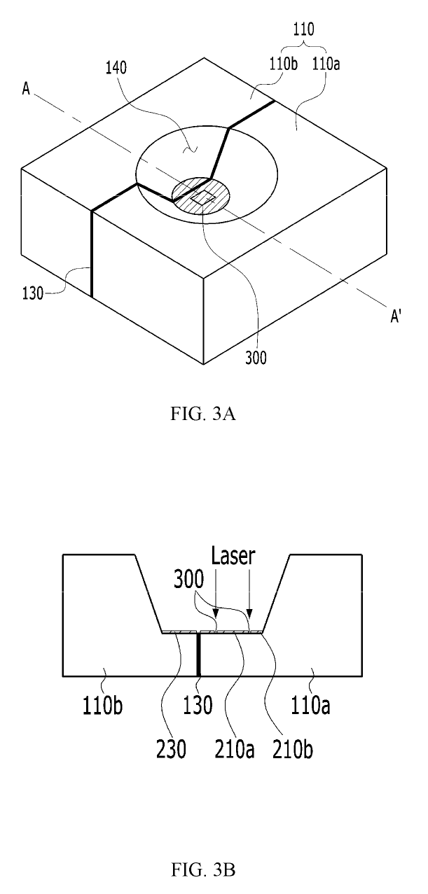

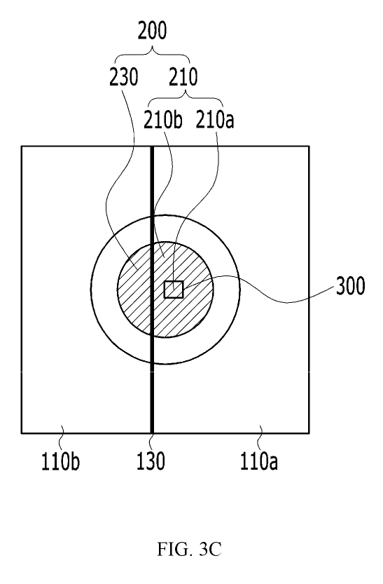

Next, as shown in FIGS. 3A to 3C, the plating layers are subjected to patterning with a laser by using the substrate for the optical device shown in FIGS. 2A to 2C. In other words, the first plating layer 210 formed on the bottom surface 170 of the cavity of the first metal member 110a is patterned with a laser such that a space region 300 is formed to expose the top surface of the first metal member 110a. Herein, a first island plating layer 210a is formed inside of the space region 300 and a first peripheral plating layer 210b is formed outside of the space region 300.

The first island plating layer 210a serves to provide a mounting region in which the optical device 500 is mounted and thus has a shape corresponding to a horizontal cross-sectional shape of the optical device 500. For example, when the optical device 500 is polygonal in horizontal cross-section, the first island plating layer 210a is also polygonal in the horizontal cross-section.

A region of the first plating layer 210 radiated with a laser is removed to expose the top surface of the first metal member 110a, thus forming the space region 300. The space region 300 is formed between the first island plating layer 210a and the first peripheral plating layer 210b such that the first island plating layer 210a and the first peripheral plating layer 210b are isolated from each other.

The space region 300 is formed in a quadrangular shape. In this case, the first island plating layer 210a and the first peripheral plating layer 210b are spaced apart from each other with the quadrangular space region 300 interposed therebetween.

Referring to FIGS. 3A to 3C, the first peripheral plating layer 210b, the space region 300, and the first island plating layer 210a are located at a first side with respect to the vertical insulating part 130, while the second plating layer 230 is located at a second side with respect to the vertical insulating part 130. In other words, the second plating layer 230, the vertical insulating part 130, the first peripheral plating layer 210b, the space region 300, and the first island plating layer 210a are located sequentially along the line intersecting with the vertical insulating part 130 from the left to the right.

The space region 300 is located at a position spaced apart from the vertical insulating part 130 at a predetermined interval (spaced apart at a predetermined interval to the right side of the vertical insulating part 130 with reference to FIGS. 3A to 3C). The first island plating layer 210a is located inside of the space region 300, and the first peripheral plating layer 210b is located on the bottom surface 170 of the cavity at the first side with respect to the vertical insulating part 130 (at the right side of the vertical insulating part 130 with reference to FIGS. 3A to 3C) at a position except for the space region 300 and the first island plating layer 210a.

The second plating layer 230 formed at the second side with respect to the vertical insulating part 130 (at the left side of the vertical insulating part 130 with reference to FIGS. 3A to 3C) is not radiated with a laser. Because of this, the second plating layer 230 as shown in FIGS. 2A to 2C is left. As described above, the plating layer 200 as shown in FIGS. 2A to 2C is left except for a portion of the plating layer 200 where the space region 300 is located. This can minimize loss of the purpose of forming the plating layer 200 on the bottom surface 170 of the cavity, while preventing a reduction in reflection efficiency through the configurations of the first peripheral plating layer 210b and the second plating layer 230.

The substrate for the optical device having been manufactured through the above process is shown in FIGS. 1A to 3C.

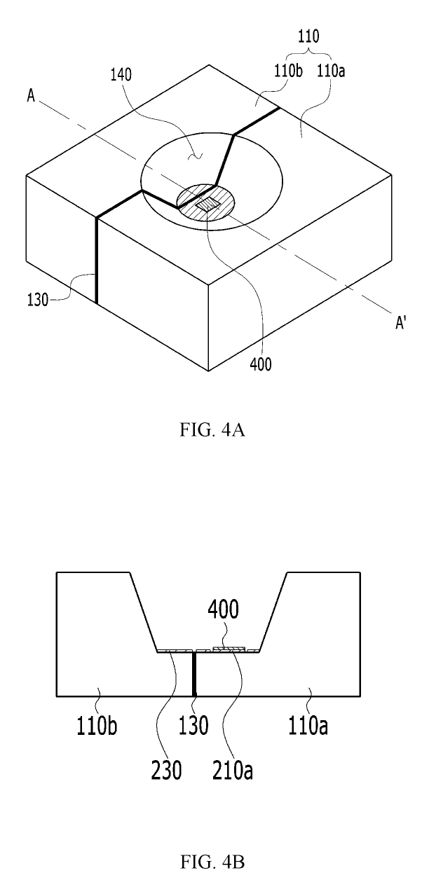

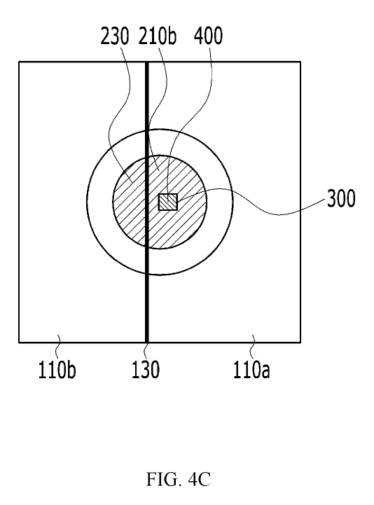

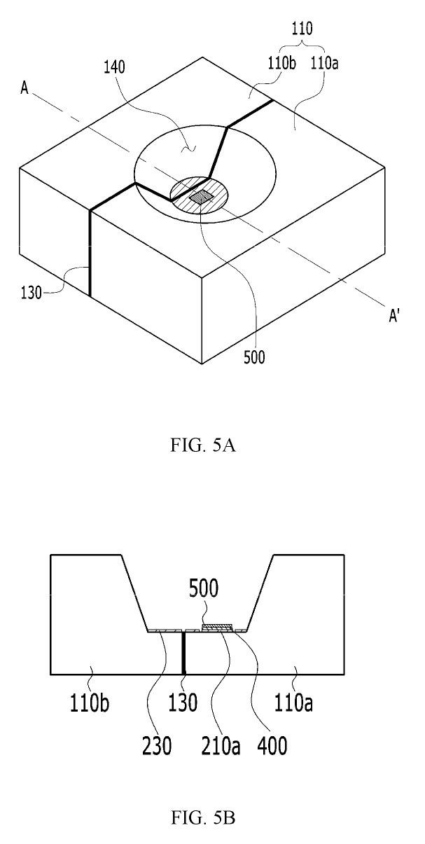

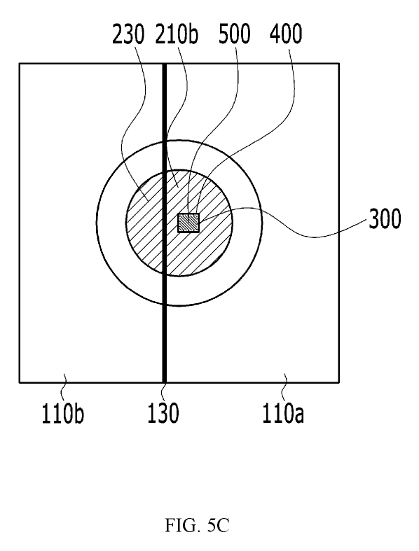

Next, a manufacturing process of an optical device package in which an optical device is mounted will be described with reference to FIGS. 4A to 5C. As shown in FIGS. 4A to 4C, a solder 400 is provided on the first island plating layer 210a by using the substrate for the optical device shown in FIGS. 3A to 3C. Thereafter, as shown in FIGS. 5A to 5C, the optical device 500 is bonded onto the solder 400.

The solder 400 may be Au—Sn solder, Sn—Ag solder, Sn—Ag—Cu solder, Sn—Zn solder, Sn—Pb solder, or Sn—Cu solder. On the other hand, the solder 400 may be solder paste, and soldering may be performed in a manner that the solder 400 is pre-heated in a reflow machine while passing therethrough and melted. In the reflow machine, melting the flux in the solder 400 and drying are performed after preheating, and a lead component of the solder 400 is melted in a reflow section and the optical device 500 is bonded thereby, and finally cooling is performed. In such a process of bonding the optical device 500, there occurs a wetting phenomenon in which the molten solder 400 spreads out on the surface of the first island plating layer 210a, causing the solder 400 to spread out evenly on the first island plating layer 210a.

As a result, even when there occurs misalignment of the optical device 500 when the optical device 500 is mounted on the solder 400, the wetting phenomenon also causes a metal layer of the optical device 500 to react with the solder, whereby the optical device 500 self-aligns to correspond to the shape of the first island plating layer 210a. This can exhibit an effect of correcting misalignment of the optical device 500.

Meanwhile, in order to construct a long optical path by condensing light emitted from the optical device 500, it is necessary that the cavity is formed to have a depth larger than a cross-sectional width. However, in the case of forming the island plating layer by patterning through a photolithography process using a mask, the distance between the mask and the bottom of the cavity is long, which makes precise patterning difficult and thus makes precise formation of the island plating layer difficult. As a result, even when the island plating layer is formed, the effect of correcting misalignment of the optical device to be mounted becomes insignificant. On the other hand, in the case of forming the island plating layer by removing a portion of the plating layer by laser radiation according to the embodiment of the present invention, it is possible to precisely form the island plating layer even when it is necessary to form a deep cavity, thus exhibiting the effect of correcting misalignment of the optical device to be mounted.

Furthermore, even when the solder 400 overflows on the first island plating layer 210a, the space region 300 prevents the solder 400 from spreading out onto the first peripheral plating layer 210b. This makes it possible to prevent the solder 400 from being formed in a shape different from the surface shape of the first island plating layer 210a.

In a case where the first and second metal members 110a and 110b are metals having affinity for the solder, such as copper or copper alloy, when the solder 400 overflows on the first island plating layer 210a, the solder 400 spreads out even onto the top surfaces of the first and second metal members 110a and 110b. Because of this, an effect that the optical device self-aligns to correspond to the cross-sectional shape of the first island plating layer 210a is not exhibited. However, according to the embodiment of the present invention, the first and second metal members 110a and 110b are made of metal having no affinity for the solder (for example, aluminum or aluminum alloy), and the space region 300 is formed in the periphery of the first island plating layer 210a and exposes the top surfaces of the first and second metal members 110a and 110b. Thus, even when the solder 400 overflows on the first island plating layer 210a, the solder spreads out only on the top and side surfaces of the first island plating layer 210a but does not spread out onto the top surfaces of the first and second metal members 110a and 110b. This causes the optical device 500 being in a tilted position to self-align to correspond to the cross-sectional shape of the first island plating layer 210a.

Furthermore, because the optical device 500 is soldered on the first island plating layer 210a, the difference in height between the optical device 500 and each of the first peripheral plating layer 210b and the second plating layer 230 is minimized. This makes it possible to mount the optical device 500 more closely to the bottom surface 170 of the cavity. As a result, light emitted from the optical device 500 and directed toward the bottom surface 170 of the cavity is reflected by the first peripheral plating layer 210b and the second plating layer 230, thus improving reflection efficiency. Additionally, the path of light reflected by the bottom surface 170 is reduced, thus improving efficiency of the optical device package.

Although not shown in the drawings, the optical device 500 shown in FIGS. 5A to 5C may be an optical device having a first terminal provided at a lower portion thereof and a second terminal provided at an upper portion thereof. Such an optical device is configured such that the first terminal is soldered and electrically connected to the first metal member 110a through the first island plating layer 210a while the second terminal is electrically connected to the second metal member 110b through a wire.

Meanwhile, a substrate cover (not shown) is provided on the top surface of the metal member 110 and is made of a transparent material. The material of the substrate cover may vary depending on the type of the optical device and may be quartz, for example.

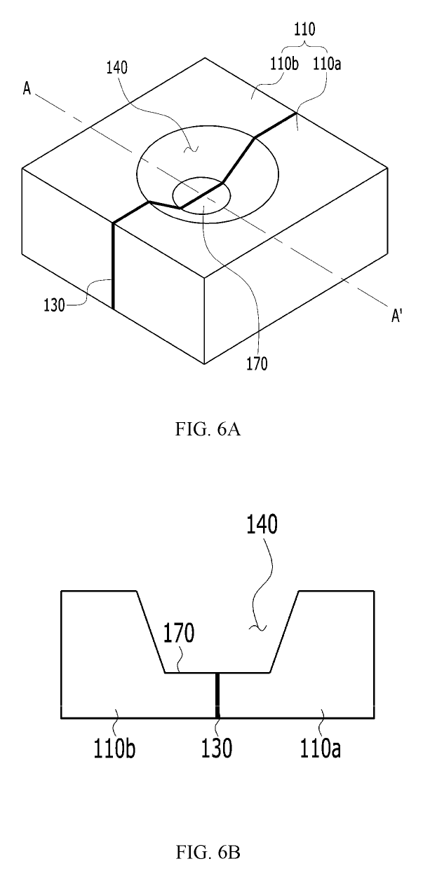

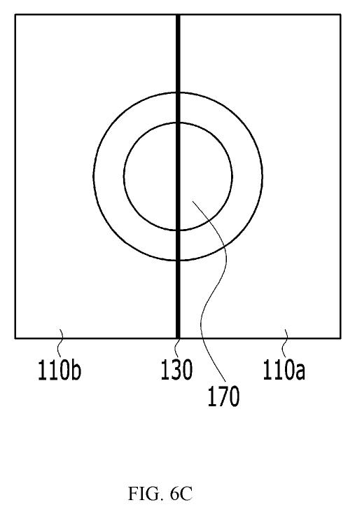

FIGS. 6A to 10C are views showing a substrate for an optical device and a manufacturing method of an optical device package according to a second embodiment of the present invention.

As shown in FIGS. 6A to 6C, first and second metal members 110a and 110b are bonded together with a vertical insulating part 130 interposed therebetween. Thereafter, a cavity 140 having a predetermined depth is formed in top surfaces of the first and second metal members 110a and 110b in a region including the vertical insulating part 130.

The substrate for the optical device shown in FIGS. 6A to 6C is configured such that the first and second metal members 110a and 110b are bonded together to define a metal member 110. In other words, the substrate for the optical device includes the first metal member 110a, the second metal member 110b located on a side surface of the first metal member 110a and bonded to the first metal member 110a, and the vertical insulating part 130 provided at a junction of the first metal member 110a and the second metal member 110b and electrically insulating the first metal member 110a and the second metal member 110b from each other.

It is preferable that the first and second metal members 110a and 110b are made of metal having no affinity for the solder. In the embodiment of the present invention, the first and second metal members 110a and 110b are made of aluminum or an aluminum alloy.

The vertical insulating part 130 is made of a material having an insulating property. The vertical insulating part 130 is provided by using an insulating liquid bonding agent. To improve the bonding strength between the first and second metal members 110a and 110b and the vertical insulating part 130 bonded together by using the liquid bonding agent, a synthetic resin bonding film may be interposed therebetween. Alternatively, at least one surface of each of the first and second metal members 110a and 110b may be subjected to anodizing and the first and second metal members 110a and 110b are bonded together in a state in which the respective anodized surfaces thereof face each other. In other words, when the first and second metal members 110a and 110b are made of aluminum (or aluminum alloy), at least one surface of each of the first and second metal members 110a and 110b is subjected to anodizing before bonding so as to be included in the vertical insulating part 130.

The substrate 100 for the optical device has the cavity 140 recessed in a top surface thereof with a predetermined depth in the region including the vertical insulating part 130. The cavity 140 has a tapered shape in which an upper portion is open and a lower portion defines a flat bottom surface 170.

The vertical insulating part 130 is located along a center line of the metal member 110. Accordingly, a portion of the bottom surface 170 of the cavity 140 located between the vertical insulating part 130 and the first metal member 110a is substantially the same in area as a remaining portion of the bottom surface 170 of the cavity 140 located between the vertical insulating part 130 and the second metal member 110b.

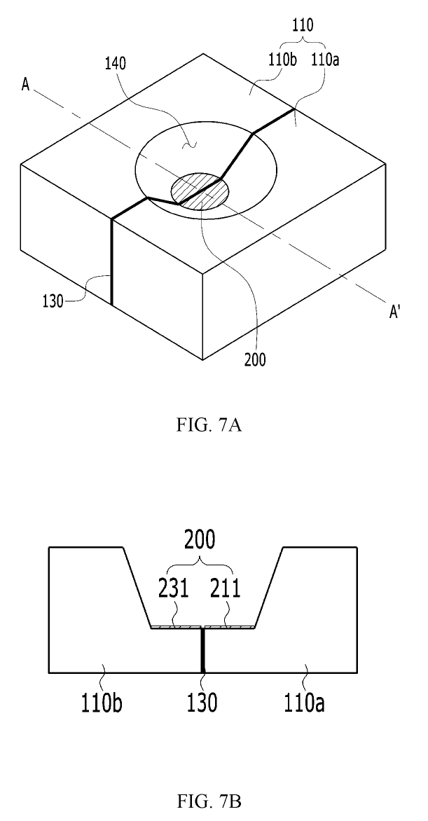

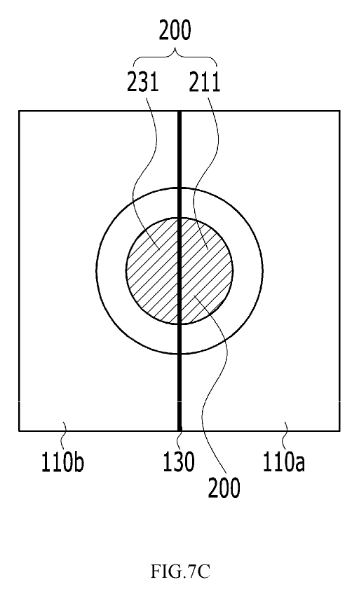

Next, as shown in FIGS. 7A to 7C, a plating layer 200 is formed on the bottom surface 170 of the cavity 140 by using the substrate for the optical device shown in FIGS. 6A to 6C.

The plating layer 200 is not famed on a top surface of the vertical insulating part 130 but includes a first plating layer 211 formed on the top surface of the first metal member 110a and a second plating layer 231 formed on the top surface of the second metal member 110b.

The first and second plating layers 211 and 231 are integrally formed through a single plating process and are made of the same metal. Furthermore, it is preferable that the first and second plating layers are made of metal having a higher reflectivity than the first and second metal members 110a and 110b. It is more preferable that the first and second plating layers are formed by plating with gold or silver.

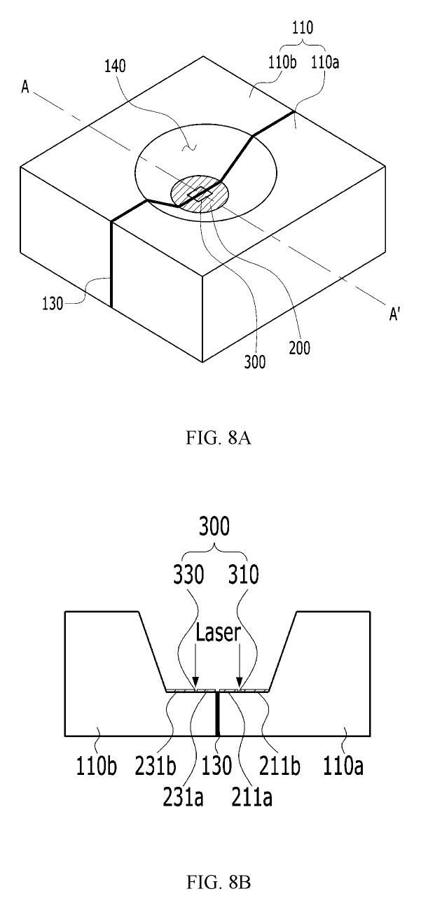

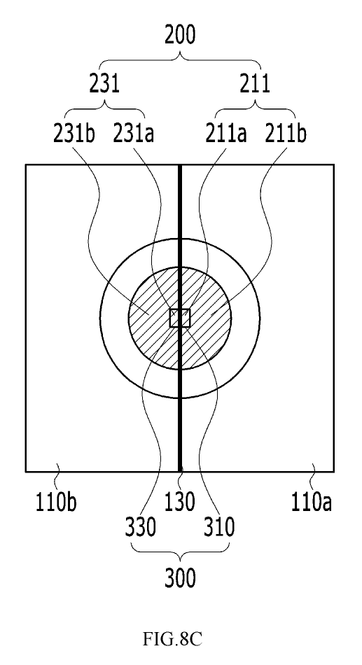

Next, as shown in FIGS. 8A to 8C, the plating layer 200 is subjected to patterning with a laser by using the substrate for the optical device shown in FIGS. 7A to 7C. In other words, the plating layer 200 formed on the bottom surface 170 of the cavity of the first and second metal members 110a and 110b is patterned with a laser such that first and second space regions 310 and 330 are formed to expose the top surfaces of the first and second metal members 110a and 110b, respectively. Herein, a first island plating layer 211a is formed inside of the first space region 310 and a first peripheral plating layer 211b is formed outside of the first space region 310, while a second island plating layer 231a is formed inside of the second space region 330 and a second peripheral plating layer 231b is famed outside of the second space region 330.

The first and second island plating layers 211a and 231a serve to provide a mounting region in which the optical device 500 is mounted and thus have a shape corresponding to a horizontal cross-sectional shape of the optical device 500. For example, when the optical device 500 is polygonal in horizontal cross-section, each of the first and island plating layers 211a and 231a is also polygonal in the horizontal cross-section. Herein, because the vertical insulating part 130 is located between the first and second island plating layers 211a and 231a, the sum of the horizontal cross-sectional areas of the first and second island plating layers 211a and 231a is smaller than the horizontal cross-sectional area of the optical device 500.

A space region 300 is formed in the plating layer 200 that is radiated with a laser. In other words, a region of the first plating layer 210 radiated with a laser is removed to expose the top surface of the first metal member 110a, thus forming the first space region 310, and a region of the second plating layer 230 radiated with a laser is removed to expose the top surface of the second metal member 110b, thus forming the second space region 330.

The first space region 310 is located at a first side with respect to the vertical insulating part 130 (at the right side of the vertical insulating part 130 with reference to FIGS. 8A to 8C), and the second space region 330 is located at a second side with respect to the vertical insulating part 130 (at the left side of the vertical insulating part 130 with reference to FIGS. 8A to 8C).

The first peripheral plating layer 211b is located on the bottom surface 170 of the cavity at the first side with respect to the vertical insulating part 130 (at the right side of the vertical insulating part 130 with reference to FIGS. 8A to 8C) at a position except for the first space region 310 and the first island plating layer 211a. The second peripheral plating layer 231b is located on the bottom surface 170 of the cavity at the second side with respect to the vertical insulating part 130 (at the left side of the vertical insulating part 130 with reference to FIGS. 8A to 8C) at a position except for the second space region 330 and the second island plating layer 231a.

The first space region 310 is formed between the first island plating layer 211a and the first peripheral plating layer 211b such that the first island plating layer 211a and the first peripheral plating layer 211b are isolated from each other. Furthermore, the second space region 330 is formed between the second island plating layer 231a and the second peripheral plating layer 231b such that the second island plating layer 231a and the second peripheral plating layer 231b are isolated from each other

As shown in FIGS. 8A to 8C, the first space region 310 is formed in a ‘ [symbol] ’-shape, and the second space region 330 is formed in a ‘ [symbol] ’-shape. Alternatively, the first and second space regions 310 and 330 may be formed in a quadrangular shape.

As shown in FIGS. 8A to 8C, the vertical insulating part 130 is interposed between the first and second space regions 310 and 330 at a position directly adjacent thereto. The first peripheral plating layer 211b may be located on the top surface of the first metal member 110a between the first space region 310 and the vertical insulating part 130, and the second peripheral plating layer 231b may be located on the top surface of the second metal member 110b between the second space region 330 and the vertical insulating part 130.

As described above, the plating layer 200 as shown in FIGS. 7A to 7C is left except for a portion of the plating layer 200 where the space region 300 is located. This can minimize loss of the purpose of forming the plating layer 200 on the bottom surface 170 of the cavity, while preventing a reduction in reflection efficiency through the configurations of the first peripheral plating layer 211b and the second peripheral plating layer 231b.

The substrate for the optical device having been manufactured through the above process is shown in FIGS. 6A to 8C.

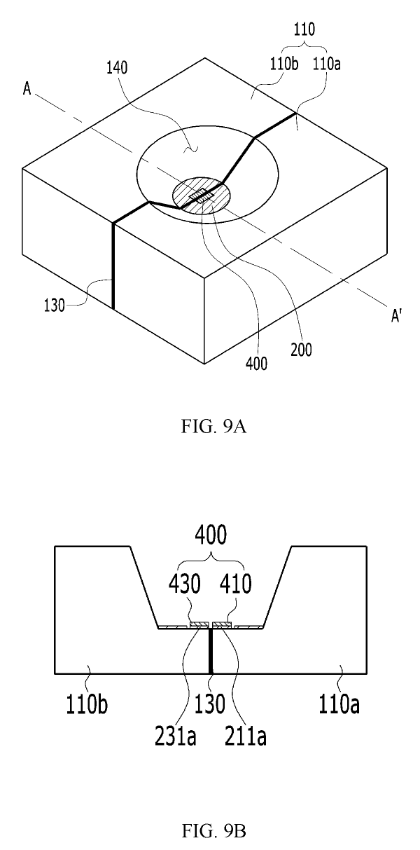

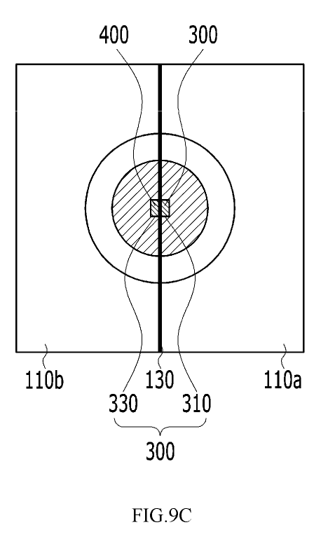

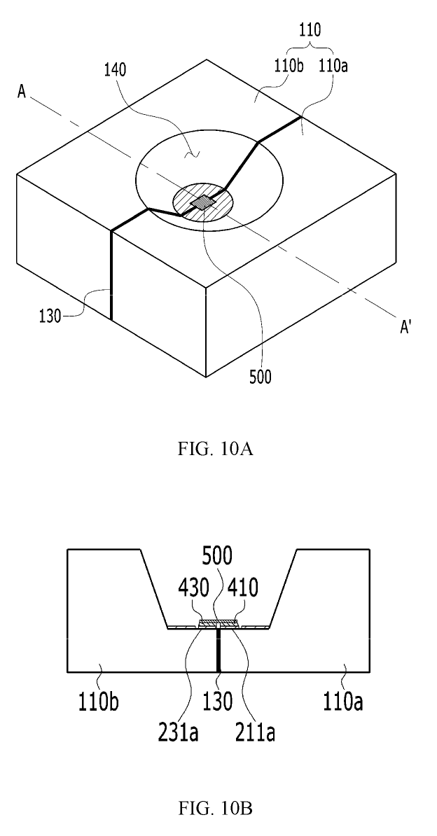

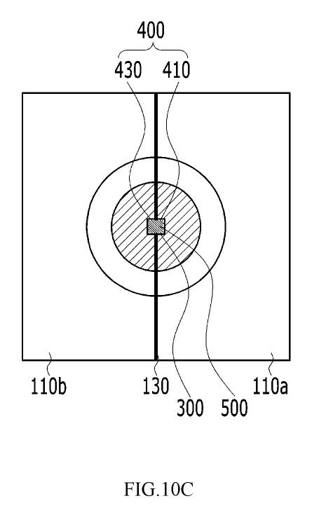

Next, a manufacturing process of an optical device package in which an optical device is mounted will be described with reference to FIGS. 9A to 10C. As shown in FIGS. 9A to 9C, a solder 400 is provided by using the substrate for the optical device shown in FIGS. 8A to 8C. In other words, a first solder 410 is provided on the first island plating layer 211a, and a second solder 430 is provided on the second island plating layer 231a. Thereafter, as shown in FIGS. 10A to 10C, the optical device 500 is bonded onto the first and second solders 410 and 430.

The first and second solders 410 and 430 may be Au—Sn solder, Sn—Ag solder, Sn—Ag—Cu solder, Sn—Zn solder, Sn—Pb solder, or Sn—Cu solder. On the other hand, each of the first and second solders 410 and 430 may be solder paste, and soldering may be performed in a manner that the first and second solders 410 and 430 is pre-heated in a reflow machine while passing therethrough and melted. In the reflow machine, melting the flux in the first and second solders 410 and 430 and drying are performed after preheating, and a lead component of the first and second solders 410 and 430 is melted in a reflow section and the optical device 500 is bonded thereby, and finally cooling is performed. In such a process of bonding the optical device 500, there occurs a wetting phenomenon in which the molten first and second solders 410 and 430 spread out on the surface of the first island plating layer 211a and the second island plating layer 231a, causing the first and second solders 410 and 430 to spread out evenly on the first island plating layer 211a and the second island plating layer 231a.

As a result, even when there occurs misalignment of the optical device 500 when the optical device 500 is mounted on the first and second solders 410 and 430, the wetting phenomenon also causes a metal layer of the optical device 500 to react with the solder, whereby the optical device 500 self-aligns to correspond to the shapes of the first island plating layer 211a and the second island plating layer 231a. This can exhibit an effect of correcting misalignment of the optical device 500.

Meanwhile, in order to construct a long optical path by condensing light emitted from the optical device 500, it is necessary that the cavity is formed to have a depth larger than a cross-sectional width. However, in the case of forming the island plating layer by patterning through a photolithography process using a mask, the distance between the mask and the bottom of the cavity is long, which makes precise patterning difficult and thus makes precise formation of the island plating layer difficult. As a result, even when the island plating layers are formed, the effect of correcting misalignment of the optical device to be mounted becomes insignificant. On the other hand, in the case of forming the island plating layer by removing a portion of the plating layer by laser radiation according to a preferred embodiment of the present invention, it is possible to precisely form the island plating layer even when it is necessary to form a deep cavity, thus exhibiting the effect of correcting misalignment of the optical device to be mounted.

Furthermore, the space region 300 prevents the first and second solders 410 and 430 from spreading out onto the first and second peripheral plating layers 211b and 231b, and the vertical insulating part 130 that also has no affinity for the solder prevents the first and second solders 410 and 430 from spreading out onto the vertical insulating part 130. Accordingly, even when the first and second solders 410 and 430 overflow on the first and second island plating layers 211a and 231a, it is possible to prevent the first and second solders 410 and 430 from being formed in a shape different from the surface shapes of the first and second island plating layers 211a and 231a.

In a case where the first and second metal members 110a and 110b are metals having affinity for the solder, such as copper or copper alloy, when the first and second solders 410 and 430 overflow on the first and second island plating layers 211a and 231a, the first and second solders 410 and 430 spread out even onto the top surfaces of the first and second metal members 110a and 110b. Because of this, an effect that the optical device self-aligns to correspond to the cross-sectional shapes of the first and second island plating layers 211a and 231a is not exhibited. However, according to the embodiment of the present invention, the first and second metal members 110a and 110b are made of metal having no affinity for the solder (for example, aluminum or aluminum alloy), and the space region 300 is formed in the peripheries of the first and second island plating layers 211a and 231a and exposes the top surfaces of the first and second metal members 110a and 110b. Thus, even when the first and second solders 410 and 430 overflow on the first and second island plating layers 211a and 231a, the solders spread out only on the top and side surfaces of the first and second island plating layers 211a and 231a but does not spread out onto the top surfaces of the first and second metal members 110a and 110b. This causes the optical device 500 being in a tilted position to self-align to correspond to the cross-sectional shapes of the first and second island plating layers 211a and 231a.

Furthermore, because the optical device 500 is soldered on the first and second island plating layers 211a and 231a, the difference in height between the optical device 500 and each of the first peripheral plating layer 211b and the second peripheral plating layer 231b is minimized. This makes it possible to mount the optical device 500 more closely to the bottom surface 170 of the cavity. As a result, light emitted from the optical device 500 and directed toward the bottom surface 170 of the cavity is reflected by the first peripheral plating layer 211b and the second peripheral plating layer 231b, thus improving reflection efficiency. Additionally, the path of light reflected by the bottom surface 170 is reduced, thus improving efficiency of the optical device package.

Although not shown in the drawings, the optical device 500 shown in FIGS. 10A to 10C may be an optical device having first and second terminals provided at a lower portion thereof. Such an optical device is configured such that the first terminal is soldered and electrically connected to the first metal member 110a through the first island plating layer 211a while the second terminal is soldered and electrically connected to the second metal member 110b through the second island plating layer 231a.

Meanwhile, a substrate cover (not shown) is provided on the top surface of the metal member 110 and is made of a transparent material. The material of the substrate cover may vary depending on the type of the optical device and may be quartz, for example.

Although the exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A substrate for an optical device, the substrate comprising:
first and second metal members bonded together with a vertical insulating part interposed therebetween;
a first island plating layer formed on a top surface of the first metal member;
a space region formed outside of the first island plating layer to expose the top surface of the first metal member;
a first peripheral plating layer formed on the top surface of the first metal member except for the first island plating layer and the space region; and
a second plating layer formed on a top surface of the second metal member.

2. The substrate of claim 1, wherein the first island plating layer has a polygonal shape, and
the space region is formed between the first island plating layer and the first peripheral plating layer such that the first island plating layer and the first peripheral plating layer are isolated from each other.

3. The substrate of claim 1, wherein the first island plating layer, the first peripheral plating layer, and the second plating layer are made of the same metal.

4. The substrate of claim 1, wherein the first peripheral plating layer, the space region, and the first island plating layer are located at a first side with respect to the vertical insulating part,
the second plating layer is located at a second side with respect to the vertical insulating part, and
the second plating layer, the vertical insulating part, the first peripheral plating layer, the space region, and the first island plating layer are located sequentially along a line intersecting with the vertical insulating part.

5. A substrate for an optical device, the substrate comprising:
first and second metal members bonded together with a vertical insulating part interposed therebetween;
a first island plating layer formed on a top surface of the first metal member;
a first space region formed outside of the first island plating layer to expose the top surface of the first metal member;
a first peripheral plating layer formed on the top surface of the first metal member except for the first island plating layer and the first space region;
a second island plating layer formed on a top surface of the second metal member;
a second space region formed outside of the second island plating layer to expose the top surface of the second metal member; and
a second peripheral plating layer formed on the top surface of the second metal member except for the second island plating layer and the second space region.

6. The substrate of claim 5, wherein the first space region has a ‘ [symbol] ’-shape,
the second space region has a ‘ [symbol] ’-shape, and
the vertical insulating part is located between the first and second space regions that face each other.

7. An optical device package, comprising:
first and second metal members bonded together with a vertical insulating part interposed therebetween;
a first island plating layer formed on a top surface of the first metal member;
a space region formed outside of the first island plating layer to expose the top surface of the first metal member;
a first peripheral plating layer formed on the top surface of the first metal member except for the first island plating layer and the space region;
a second plating layer formed on a top surface of the second metal member;
a solder provided on the first island plating layer;
an optical device provided on the solder and having a first terminal electrically connected to the first metal member; and
a wire electrically connecting a second terminal of the optical device to the second metal member.

8. The optical device package of claim 7, wherein the first and second metal members are metals that have no affinity for the solder.
